(19) United States
(12) Patent Application Publication
(10) Pub. No.: US 2023/0260866 A1
(43) Pub. Date: Aug. 17, 2023

(54) SEMICONDUCTOR PACKAGE STRUCTURE

(71) Applicant: MEDIATEK INC., Hsinchu City (TW)

(72) Inventors: Yin-Fa CHEN, Hsinchu City (TW); Bo-Jiun YANG, Hsinchu City (TW); Ta-Jen YU, Hsinchu City (TW); Bo-Hao MA, Hsinchu City (TW); Chih-Wei CHANG, Hsinchu City (TW); Tsung-Yu PAN, Hsinchu City (TW); Tai-Yu CHEN, Hsinchu City (TW); Shih-Chin LIN, Hsinchu City (TW); Wen-Sung HSU, Hsinchu City (TW)

(21) Appl. No.: 18/157,159

(22) Filed: Jan. 20, 2023

Related U.S. Application Data
(60) Provisional application No. 63/311,102, filed on Feb. 17, 2022.

(51) Int. Cl. H01L 23/367; H01L 23/00; H01L 23/498; H01L 23/13

(52) U.S. Cl. CPC H01L 23/3675; H01L 24/73; H01L 24/16; H01L 24/32; H01L 24/17; H01L 23/49816; H01L 23/49833; H01L 23/49838; H01L 23/13; H01L 2924/1511; H01L 2924/15151; H01L 2924/152; H01L 2924/15331; H01L 2224/16227; H01L 2224/73204; H01L 2224/73253; H01L 2224/32059; H01L 2224/32225; H01L 2224/17051; H01L 2924/1011

(57) ABSTRACT

A semiconductor package structure includes a package substrate, a semiconductor die, an interposer, an adhesive layer, and a molding material. The semiconductor die is disposed over the package substrate. The interposer is disposed over the semiconductor die. The adhesive layer connects the semiconductor die and the interposer. The molding material surrounds the semiconductor die and the adhesive layer.

### CROSS REFERENCE TO RELATED APPLICATIONS

This application claims the benefit of U.S. Provisional Application No. 63/311,102 filed on Feb. 17, 2022, the entirety of which is incorporated by reference herein.

### BACKGROUND OF THE INVENTION

### Field of the Invention

The present invention is related to semiconductor packaging technology, and in particular to a semiconductor package structure.

### Description of the Related Art

A semiconductor package structure can not only provide a semiconductor die with protection from environmental contaminants, but it can also provide an electrical connection between the semiconductor die packaged therein and a substrate, such as a printed circuit board (PCB). With the increase in demand for smaller devices that can perform more functions, package-on-package (PoP) technology has become increasingly popular. The PoP technology vertically stacks two or more package structures, so that the amount of area that it takes up on the motherboard can be reduced.

However, although existing semiconductor package structures generally meet requirements, they are not satisfactory in every respect. For example, if the heat which is generated during the operation of the semiconductor die is not adequately removed, the increased temperatures may result in damage to semiconductor components. Thermal dissipation is a critical problem that needs to be solved since it affects the performance of semiconductor package structures. Therefore, further improvements in semiconductor package structures are required.

### BRIEF SUMMARY OF THE INVENTION

Semiconductor package structures are provided. An exemplary embodiment of a semiconductor package structure includes a package substrate, a semiconductor die, an interposer, an adhesive layer, and a molding material. The semiconductor die is disposed over the package substrate. The interposer is disposed over the semiconductor die. The adhesive layer connects the semiconductor die and the interposer. The molding material surrounds the semiconductor die and the adhesive layer.

Another exemplary embodiment of a semiconductor package structure includes a package substrate, a semiconductor die, an interposer, an adhesive layer, and a conductive structure. The semiconductor die is disposed over the package substrate. The interposer is disposed over the semiconductor die and has a first bottom surface, a second bottom surface, and a sidewall connecting the first bottom surface and the second bottom surface. The adhesive layer connects the semiconductor die and the first bottom surface of the interposer. The conductive structure connects the package substrate and the second bottom surface of the interposer.

Yet another exemplary embodiment of a semiconductor package structure includes a package substrate, an interposer, a semiconductor die, and a molding material. The interposer is disposed over the package substrate and has a cavity. The semiconductor die is disposed over the package substrate and in the cavity. The molding material surrounds the semiconductor die and extends into the cavity.

### BRIEF DESCRIPTION OF THE DRAWINGS

The present invention can be more fully understood by reading the subsequent detailed description and examples with references made to the accompanying drawings, wherein:

FIGS. 1A, 1B and 1C are cross-sectional views illustrating a semiconductor package structure at various stages of manufacture in accordance with some embodiments of the present disclosure.

FIGS. 2, 3, 4, 5, 6 and 7 are cross-sectional views illustrating semiconductor package structures in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “forming a first element over a second element” may include embodiments in which the first element is in direct contact with the second element, and may also include embodiments in which additional elements are disposed between the first element and the second element such that the first element and the second element are not in direct contact.

Spatially relative descriptors of the first element and the second element may change as the device is operated or used in different orientations. In addition, the present disclosure may repeat reference numerals and/or letters in the various embodiments. This repetition is for simplicity and clarity and does not in itself dictate a relationship between the various embodiments discussed.

A semiconductor package structure with enhanced efficiency of thermal dissipation is described in accordance with some embodiments of the present disclosure. The thermal dissipation path can be shortened, and thus the performance of the semiconductor package structure can be improved. The present disclosure can be adopted as a phone thermal solution.

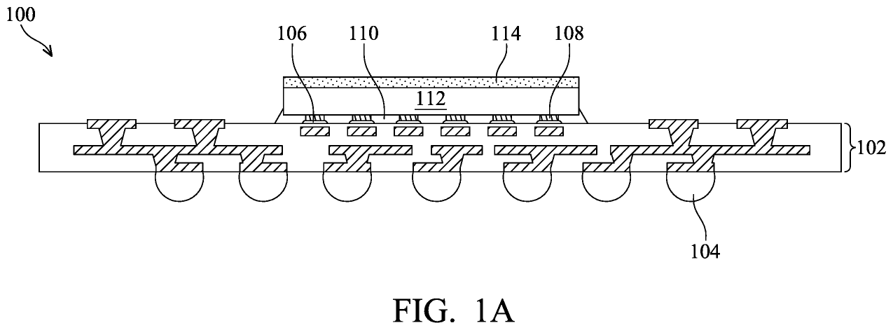

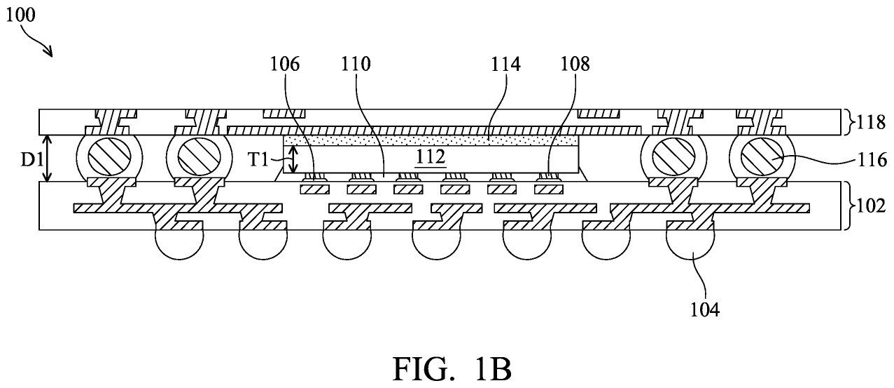

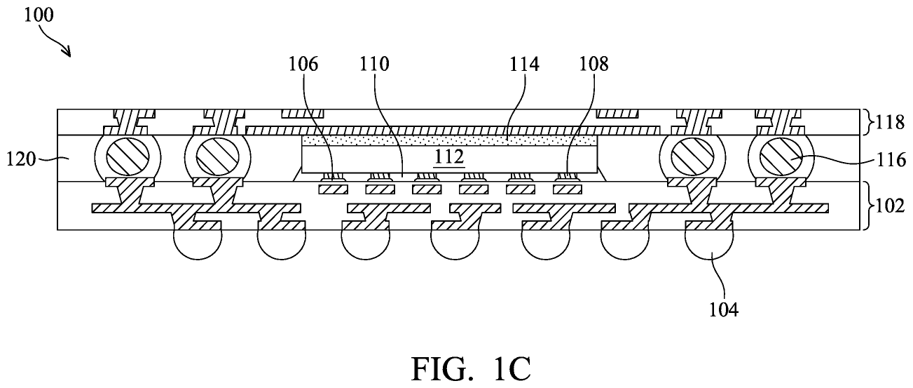

FIGS. 1A to 1C are cross-sectional views illustrating a semiconductor package structure 100 at various stages of manufacture in accordance with some embodiments of the present disclosure. Additional features can be added to the semiconductor package structure 100. Some of the features described below can be replaced or eliminated for different embodiments. To simplify the diagram, only a portion of the semiconductor package structure 100 is illustrated.

As illustrated in FIG. 1A, a package substrate 102 is provided, in accordance with some embodiments. The package substrate 102 may have a wiring structure therein. In some embodiments, the wiring structure of the package substrate 102 includes conductive layers, conductive vias, conductive pillars, the like, or a combination thereof. The wiring structure of the package substrate 102 may be formed of metal, including copper, aluminum, tungsten, the like, an alloy thereof, or a combination thereof.

The wiring structure of the package substrate 102 may be disposed in passivation layers. The passivation layers may be formed of polymers, including polyimide (PI), polybenzoxazole (PBO), benzocyclobutene (BCB), epoxy, the like, or a combination thereof. Alternatively, the passivation layers may be formed of dielectric materials, including silicon oxide, silicon carbide, silicon nitride, silicon oxynitride, the like, or a combination thereof.

It should be noted that the configuration of the package substrate 102 shown in the figures is exemplary only and is not intended to limit the present disclosure. Any desired semiconductor element may be formed in and on the package substrate 102. However, in order to simplify the diagram, only the flat substrate 102 is illustrated.

As shown in FIG. 1A, the semiconductor package structure 100 includes a plurality of conductive terminals 104 disposed below the package substrate 102 and electrically coupled to the wiring structure of the package substrate 102, in accordance with some embodiments. The conductive terminals 104 may include microbumps, controlled collapse chip connection (C4) bumps, solder balls, ball grid array (BGA) balls, the like, or a combination thereof. In some embodiments, the conductive terminals 104 are formed of conductive material, including copper, aluminum, tungsten, the like, an alloy thereof, or a combination thereof.

As further shown in FIG. 1A, the semiconductor package structure 100 includes a semiconductor die 112 disposed over the package substrate 102, in accordance with some embodiments. In some embodiments, the semiconductor die 112 includes a system-on-chip (SoC) die, a logic device, a memory device, a radio frequency (RF) device, the like, or any combination thereof. For example, the semiconductor die 112 may include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, the like, or any combination thereof.

According to some embodiments, the semiconductor package structure 100 may include more than one semiconductor dies. In addition, the semiconductor package structure 100 may also include one or more passive components (not illustrated) adjacent to the semiconductor die 112, such as resistors, capacitors, inductors, the like, or a combination thereof.

The semiconductor die 112 may be electrically coupled to the wiring structure of the package substrate 102 through a plurality of conductive structures 108 and a plurality of connectors 106. As shown in FIG. 1A, the conductive structures 108 may be disposed below the semiconductor die 112, and may be bonded to the package substrate 102 through the connectors 106.

In some embodiments, the conductive structures 108 include conductive pads, conductive pillars, the like, or a combination thereof. The conductive structures 108 may be formed of conductive materials, including copper, aluminum, tungsten, titanium, tantalum, the like, an alloy thereof, or a combination thereof. The conductive structures 108 may be formed by electroplating, electroless plating, or any applicable processes.

In some embodiments, the connectors 106 are formed of solder materials, including tin, SnAg, SnPb, the like, or a combination thereof. The connectors 106 may be formed by electroplating, electroless plating, or any applicable process.

As illustrated in FIG. 1A, the semiconductor package structure 100 includes an underfill material 110 between the package substrate 102 and the semiconductor die 112, in accordance with some embodiments. The underfill material 110 may fill in gaps between the conductive structures 108 and the connectors 106 and surround each of them to provide structural support. In some embodiments, the underfill material 110 is formed of polymer, such as epoxy. The underfill material 110 may be dispensed with capillary force, and then be cured through any suitable curing process.

As shown in FIG. 1A, the semiconductor package structure 100 includes an adhesive layer 114 disposed over the semiconductor die 112, in accordance with some embodiments. The adhesive layer 114 may cover the entire top surface the semiconductor die 112. In some embodiments, the adhesive layer 114 includes conductive paste (CP), non-conductive paste (NCP), high-k film, epoxy, or any applicable materials. The sidewalls of the adhesive layer 114 may be substantially coplanar with the sidewalls of the semiconductor die 112.

As illustrated in FIG. 1B, an interposer 118 is bonded onto the semiconductor die 112 through the adhesive layer 114, in accordance with some embodiments. The thickness of the semiconductor die 112 is increased to gain power budget enhancement. In addition, the semiconductor die 112 is thick enough to connect the interposer 118, so that the heat from the thermal source (e.g., the semiconductor die 112) can be transferred to the interposer 118 through the adhesive layer 114. Consequently, the thermal dissipation path can be shortened.

According to some embodiments, the ratio of the thickness T1 of the semiconductor die 112 in the direction substantially vertical to the top surface of the package substrate 102 to the distance D1 between the interposer 118 and the package substrate 102 is in a range of about 0.5 to about 0.95, such as about 0.9.

The adhesive layer 114 may be disposed on the semiconductor die 112 before bonding the interposer 118 to the semiconductor die 112 as illustrated, but the present disclosure is not limited thereto. As an example, the adhesive layer 114 may be disposed on the interposer 118 before bonding the interposer 118 to the semiconductor die 112. As another example, the adhesive layer 114 may be disposed on both of the interposer 118 and the semiconductor die 112 before bonding the interposer 118 to the semiconductor die 112.

The interposer 118 may have a wiring structure therein. In some embodiments, the wiring structure of the interposer 118 includes conductive layers, conductive vias, conductive pillars, the like, or a combination thereof. The wiring structure of the interposer 118 may be formed of metal, including copper, aluminum, tungsten, the like, an alloy thereof, or a combination thereof.

The wiring structure of the interposer 118 may be disposed in passivation layers. The passivation layers may be formed of polymers, including polyimide (PI), polybenzoxazole (PBO), benzocyclobutene (BCB), epoxy, the like, or a combination thereof. Alternatively, the passivation layers may be formed of dielectric materials, including silicon oxide, silicon carbide, silicon nitride, silicon oxynitride, the like, or a combination thereof.

As shown in FIG. 1B, the semiconductor package structure 100 includes a plurality of conductive structures 116 disposed between the package substrate 102 and the interposer 118, in accordance with some embodiments. The wiring structure of the interposer 118 may be electrically coupled to the wiring structure of the package substrate 102 through the conductive structures 116. In some embodiments, the conductive structures 116 include conductive pillars, solder balls, copper core solder balls, the like, or a combination thereof. The conductive structures 116 may be formed of conductive materials, including copper, aluminum, tungsten, the like, an alloy thereof, or a combination thereof.

As illustrated in FIG. 1C, the semiconductor package structure 100 includes a molding material 120 surrounding the semiconductor die 112, the adhesive layer 114, the underfill material 110, and the conductive structures 116, in accordance with some embodiments. The molding material 120 may include a nonconductive material, such as a moldable polymer, an epoxy, a resin, the like, or a combination thereof.

The molding material 120 may protect the semiconductor die 112, the adhesive layer 114, and the conductive structures 116 from the environment, thereby preventing these components from damage due to, for example, the stress, the chemicals and/or the moisture. As shown in FIG. 1C, the sidewalls of the molding material 120 may be substantially coplanar with the sidewalls of the package substrate 102 and the sidewalls of the interposer 120.

In some embodiments where a semiconductor die is not thick enough for bonding to an interposer, a portion of a molding material is disposed therebetween. In these embodiments, since the gap between the semiconductor die and the interposer is narrow, some voids might be formed therein. In addition, low thermal conductivity of the molding material makes it difficult to dissipate heat. Opposite of these embodiments, the present disclosure includes a thicker semiconductor die 112 and connects the semiconductor die 112 and the interposer 118 with the adhesive layer 114. Therefore, voids between the semiconductor die 112 and the interposer 118 can be reduced or avoided. Moreover, since the adhesive layer 114 has a higher thermal conductivity than the molding material 120, the efficiency of thermal dissipation can be further improved.

Additionally, the semiconductor die 112 can provide a stronger support than the molding material 120, so that the semiconductor package structure 100 can have a better warpage behavior.

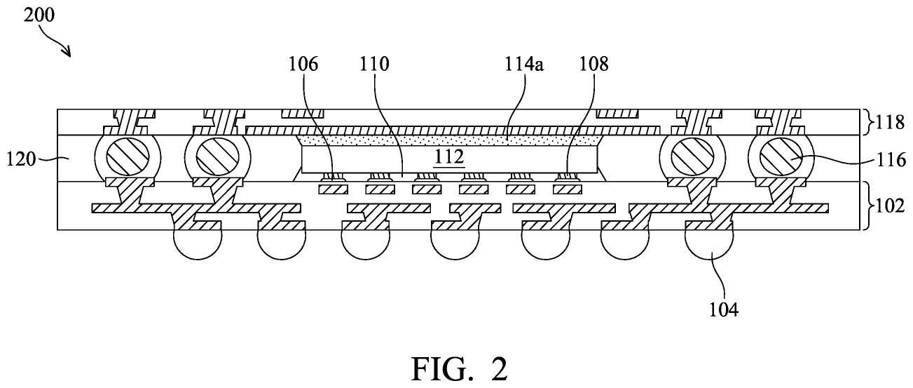

As described above, the sidewalls of the adhesive layer 114 may be substantially coplanar with the sidewalls of the semiconductor die 112, as shown in FIG. 1C, but the present disclosure is not limited thereto. As an example, a semiconductor package structure 200 includes an adhesive layer 114a which may extend outside the sidewalls of the semiconductor die 112, as shown in FIG. 2. The sidewalls of the adhesive layer 114a may be tapered. In particular, the adhesive layer 114a may have a larger projection area than the semiconductor die 112.

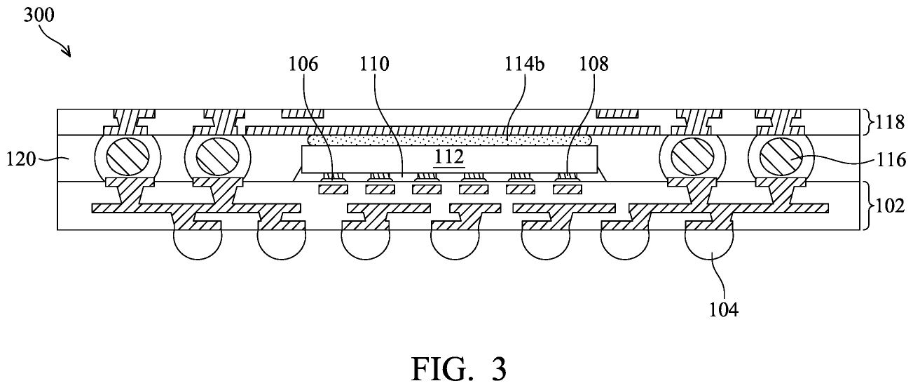

As another example, a semiconductor package structure 300 includes an adhesive layer 114b which may have sidewalls between the sidewalls of the semiconductor die 112, as shown in FIG. 3. The sidewalls of the adhesive layer 114b may be rounded. In particular, the semiconductor die 112 may have a larger projection area than the adhesive layer 114b.

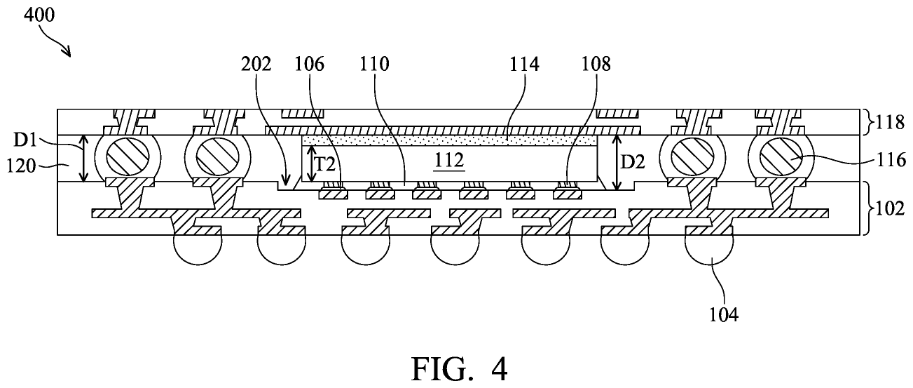

FIG. 4 is a cross-sectional view illustrating a semiconductor package structure 400 in accordance with some embodiments of the present disclosure. It should be noted that the semiconductor package structure 400 may include the same or similar components as that of the semiconductor package structure 100, which is illustrated in FIG. 1C, and for the sake of simplicity, those components will not be discussed in detail again. In the following embodiments, the package substrate has a recess for accommodating a thicker semiconductor die.

As illustrated in FIG. 4, the package substrate 102 has a recess 202, and the semiconductor die 112 is disposed directly above the recess 202, in accordance with some embodiments. In particular, the semiconductor die 112 may be disposed in the thinner region of the package substrate 102. As a result, the thickness of the semiconductor die 112 can be further increased for enhancing the thermal dissipation.

As shown in FIG. 4, the package substrate 102 may have a first top surface (i.e., the bottom surface of the recess 202) directly below the semiconductor die 112 and a second top surface in contact with the conductive structures 116. The first top surface and the second top surface of the package substrate 102 may form a stepped shape.

According to some embodiments, in regions without the recess 202, the ratio of the thickness T2 of the semiconductor die 112 in the direction substantially vertical to the top surface of the package substrate 102 to the distance D1 between the interposer 118 and the package substrate 102 is in a range of about 0.5 to about 0.98, such as about 0.9. According to some embodiments, in regions with the recess 202, the ratio of the thickness T2 of the semiconductor die 112 to the distance D2 between the interposer 118 and the package substrate 102 is in a range of about 0.5 to about 0.95, such as about 0.9. The distance D2 may be greater than the distance D1. According to some embodiments, the ratio of the distance D2 to the distance D1 is in a range of about 1.05 to about 1.5, such as about 1.07.

As further shown in FIG. 4, the sidewalls of the recess 202 may be substantially vertical to the second top surface of the package substrate 102, but the present disclosure is not limited thereto. For example, at least one of the sidewalls of the recess 202 may be tapered or sloped.

As illustrated in FIG. 4, the conductive structures 108, the connectors 106, and the underfill material 110 may be disposed in the recess 202, and a portion of the molding material 120 may extend into the recess 202. However, this may vary depending on the dimension or shape of the recess 202. For example, in some other embodiments, the underfill material 110 may fully fill the recess 202, and the molding material 120 may not extend into the recess 202.

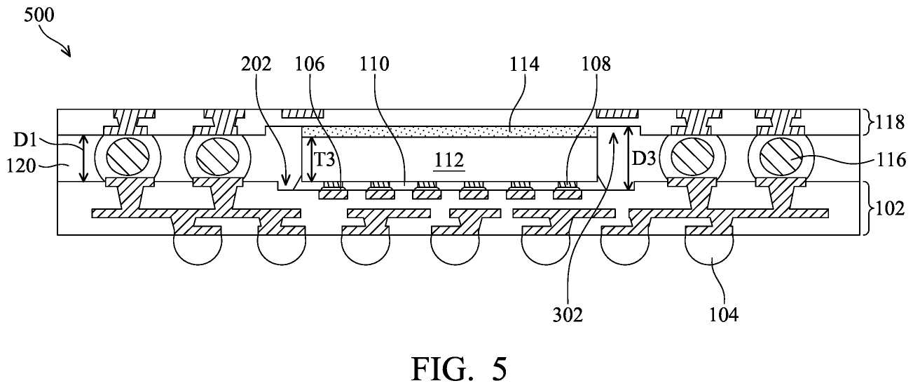

FIG. 5 is a cross-sectional view illustrating a semiconductor package structure 500 in accordance with some embodiments of the present disclosure. It should be noted that the semiconductor package structure 500 may include the same or similar components as that of the semiconductor package structure 100, which is illustrated in FIG. 1C, and for the sake of simplicity, those components will not be discussed in detail again. In the following embodiments, both of the package substrate and the interposer have recesses for accommodating a thicker semiconductor die.

As illustrated in FIG. 5, the package substrate 102 has a recess 202, and the interposer 118 has a recess 302 directly above the recess 202, in accordance with some embodiments. The semiconductor die 112 may be disposed between the recess 202 and the recess 302. In particular, the semiconductor die 112 may be disposed between the thinner region of the package substrate 102 and the thinner region of the interposer 118. As a result, the thickness of the semiconductor die 112 can be further increased for improving the thermal dissipation.

As shown in FIG. 5, the interposer 118 may have a first bottom surface in contact with the adhesive layer 114 (i.e., the bottom surface of the recess 302) and a second bottom surface in contact with the conductive structures 116. The first bottom surface and the second bottom surface of the interposer 118 may form a stepped shape.

As further shown in FIG. 5, the package substrate 102 may have a first top surface (i.e., the bottom surface of the recess 202) directly below the semiconductor die 112 and a second top surface in contact with the conductive structures 116. The first top surface and the second top surface of the package substrate 102 may form a stepped shape.

As illustrated in FIG. 5, the recess 302 may have a larger projection area than the recess 202, but the present disclosure is not limited thereto. For example, the recess 202 may have a larger projection area than the recess 302. Alternatively, the dimension of the recess 202 may be substantially equal to the dimension of the recess 302.

According to some embodiments, in regions without the recess 202 and the recess 302, the ratio of the thickness T3 of the semiconductor die 112 in the direction substantially vertical to the top surface of the package substrate 102 to the distance D1 between the interposer 118 and the package substrate 102 is in a range of about 0.5 to about 1.5, such as about 1. According to some embodiments, in regions with the recess 202 and the recess 302, the ratio of the thickness T3 of the semiconductor die 112 to the distance D3 between the interposer 118 and the package substrate 102 is in a range of about 0.5 to about 0.95, such as about 0.85. The distance D3 may be greater than the distance D1. According to some embodiments, the ratio of the distance D3 to the distance D1 is in a range of about 1.05 to about 1.5, such as about 1.07.

As shown in FIG. 5, the sidewalls of the recess 202 may be substantially vertical to the second top surface of the package substrate 102, and the sidewalls of the recess 302 may be substantially vertical to the second bottom surface of the interposer 118, but the present disclosure is not limited thereto. For example, at least one of the sidewalls of the recess 202 and the sidewalls of the recess 302 may be tapered or sloped.

As further shown in FIG. 5, the conductive structures 108, the connectors 106, and the underfill material 110 may be disposed in the recess 202. A portion of the molding material 120 may extend into the recess 202 and may cover the sidewalls of the recess 202. However, this may vary depending on the dimension or shape of the recess 202. For example, in some other embodiments, the underfill material 110 may fully fill the recess 202, and the molding material 120 may not extend into the recess 202.

As illustrated in FIG. 5, the bottom surface of the recess 302 may have a larger projection area than the adhesive layer 114. A portion of the molding material 120 may extend into the recess 302 and may cover the sidewalls of the recess 302. However, this may vary depending on the dimension or shape of the recess 302. For example, in some other embodiments, the adhesive layer 114 may fully fill the recess 302, and the molding material 120 may not extend into the recess 302.

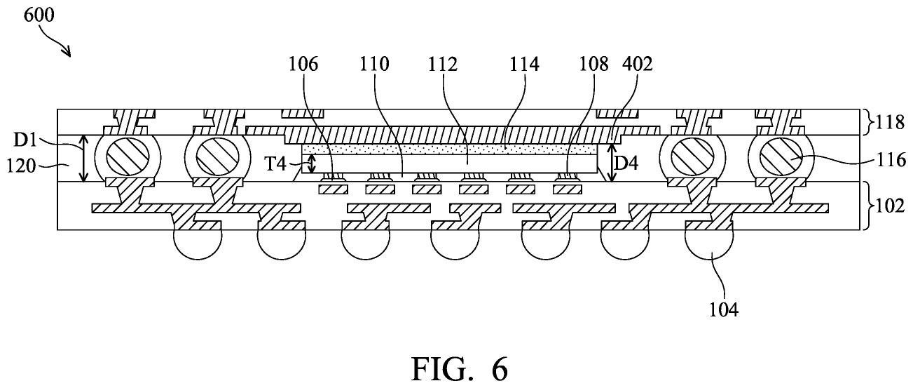

FIG. 6 is a cross-sectional view illustrating a semiconductor package structure 600 in accordance with some embodiments of the present disclosure. It should be noted that the semiconductor package structure 600 may include the same or similar components as that of the semiconductor package structure 100, which is illustrated in FIG. 1C, and for the sake of simplicity, those components will not be discussed in detail again. In the following embodiments, the interposer has a mesa structure to facilitate heat transfer from the semiconductor die.

As illustrated in FIG. 6, the interposer 118 has a mesa structure 402, and the semiconductor die 112 is disposed directly below the mesa structure 402, in accordance with some embodiments. In particular, the semiconductor die 112 may be disposed in the thicker region of the interposer 118.

According to some embodiments, the mesa structure 402 includes an embedded heat sink. The mesa structure 402 may be formed of metal, including copper, aluminum, tungsten, the like, an alloy thereof, or a combination thereof. In some embodiments, the mesa structure 402 is a portion of the wiring structure of the interposer 118 and is formed during the formation of the wiring structure of the interposer 118. In some other embodiments, the mesa structure 402 is formed after the formation of the wiring structure of the interposer 118.

As shown in FIG. 6, the interposer 118 may have a first bottom surface (i.e., the bottom surface of the mesa structure 402) directly above the semiconductor die 112 and a second bottom surface in contact with the conductive structures 116. The first bottom surface and the second bottom surface of the interposer 118 may form a stepped shape.

According to some embodiments, in regions without the mesa structure 402, the ratio of the thickness T4 of the semiconductor die 112 in the direction substantially vertical to the top surface of the package substrate 102 to the distance D1 between the interposer 118 and the package substrate 102 is in a range of about 0.2 to about 0.95, such as about 0.8. According to some embodiments, in regions with the mesa structure 402, the ratio of the thickness T4 of the semiconductor die 112 to the distance D4 between the interposer 118 and the package substrate 102 is in a range of about 0.25 to about 0.95, such as about 0.85. The distance D4 may be less than the distance D1. According to some embodiments, the ratio of the distance D4 to the distance D1 is in a range of about 0.65 to about 0.98, such as about 0.95.

As further shown in FIG. 6, the sidewalls of the mesa structure 402 may be substantially vertical to the second bottom surface of the interposer 118, but the present disclosure is not limited thereto. For example, at least one of the sidewalls of the mesa structure 402 may be tapered or sloped.

The mesa structure 402 may be surrounded by the molding material 120. As shown in FIG. 6, the mesa structure 402 may have a larger projection area than the adhesive layer 114 and the semiconductor die 112, but the present disclosure is not limited thereto. As an example, the adhesive layer 114 and/or the semiconductor die 112 may have a larger projection area than the mesa structure 402. As another example, the sidewalls of the mesa structure 402 may be aligned with the sidewalls of the adhesive layer 114 and/or the sidewalls of the semiconductor die 112.

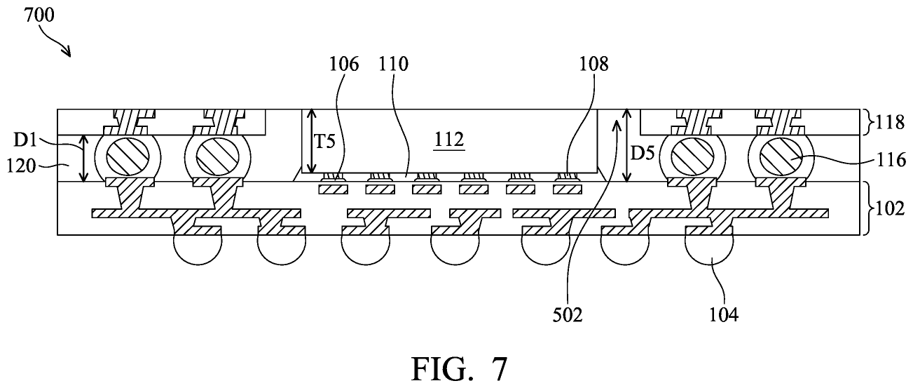

FIG. 7 is a cross-sectional view illustrating a semiconductor package structure 700 in accordance with some embodiments of the present disclosure. It should be noted that the semiconductor package structure 700 may include the same or similar components as that of the semiconductor package structure 100, which is illustrated in FIG. 1C, and for the sake of simplicity, those components will not be discussed in detail again. In the following embodiments, the interposer has a cavity for accommodating a thicker semiconductor die.

As illustrated in FIG. 7, the interposer 118 has a cavity 502, and the semiconductor die 112 is disposed in the cavity 502, in accordance with some embodiments. The thickness of the semiconductor die 112 can be further increased for improving the thermal dissipation.

According to some embodiments, in regions without the cavity 502, the ratio of the thickness T5 of the semiconductor die 112 in the direction substantially vertical to the top surface of the package substrate 102 to the distance D1 between the interposer 118 and the package substrate 102 is in a range of about 0.85 to about 1.5, such as about 1.2. According to some embodiments, in regions with the cavity 502, the ratio of the thickness T5 of the semiconductor die 112 to the distance D5 between the interposer 118 and the package substrate 102 is in a range of about 0.75 to about 0.95, such as about 0.85. The distance D5 may be greater than the distance D1. According to some embodiments, the ratio of the distance D5 to the distance D1 is in a range of about 1.15 to about 1.5, such as about 1.45.

As shown in FIG. 7, the cavity 502 may extend through interposer 118. In particular, the cavity 502 may extend from the bottom surface of the interposer 118 to the top surface of the interposer 118. The sidewalls of the cavity 502 may be substantially vertical to the bottom surface of the interposer 118, but the present disclosure is not limited thereto. For example, at least one of the sidewalls of the cavity 502 may be tapered or sloped. The molding material 120 may extend into the cavity 502 and may cover the sidewalls of the cavity 502. The top surface of the interposer 118 and the top surface of the molding material 120 may be substantially coplanar.

In some embodiments, the top surface of the semiconductor die 112 is exposed to increase the efficiency of thermal dissipation, as shown in FIG. 7. The top surface of the semiconductor die 112 may be substantially coplanar with the top surface of the interposer 118 and the top surface of the molding material 120. The dimension (such as the width) of the cavity 502 may be greater than the dimension (such as the width) of the semiconductor die 112.

In summary, in some embodiments, the semiconductor package structure according to the present disclosure increase the thickness of the semiconductor die to gain power budget enhancement. Therefore, the efficiency of thermal dissipation can be enhanced, and thus the performance of the semiconductor package structure can be improved.

According to some embodiments, the semiconductor die reaches the interposer to shorten the heat dissipation path. The better warpage behavior and fewer (or without) voids can be achieved as well. In addition, the interposer has a mesa structure to facilitate heat transfer from the semiconductor die, according to some embodiments. According to some embodiments, the top surface of the semiconductor die is exposed for better thermal dissipation.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a package substrate;
a semiconductor die disposed over the package substrate;
an interposer disposed over the semiconductor die;
an adhesive layer connecting the semiconductor die and the interposer; and
a molding material surrounding the semiconductor die and the adhesive layer.

2. The semiconductor package structure as claimed in claim 1, further comprising a conductive structure disposed between the package substrate and the interposer and surrounded by the molding material.

3. The semiconductor package structure as claimed in claim 1, wherein the semiconductor die is disposed directly above a recess of the package substrate, and the molding material extends into the recess of the package substrate.

4. The semiconductor package structure as claimed in claim 3, further comprising:
a plurality of conductive structures disposed between the semiconductor die and the package substrate; and
an underfill material surrounding the plurality of conductive structures,
wherein the plurality of conductive structures and the underfill material are disposed in the recess.

5. The semiconductor package structure as claimed in claim 1, wherein the adhesive layer is disposed in a first recess of the interposer.

6. The semiconductor package structure as claimed in claim 5, wherein the semiconductor die is disposed between the first recess of the interposer and a second recess of the package substrate, and the molding material extends into the first recess of the interposer and/or the second recess of the package substrate.

7. The semiconductor package structure as claimed in claim 1, wherein the interposer comprises a mesa structure.

8. The semiconductor package structure as claimed in claim 7, wherein the mesa structure is in contact with the adhesive layer.

9. The semiconductor package structure as claimed in claim 7, wherein the mesa structure is formed of metal.

10. A semiconductor package structure, comprising:
a package substrate;
a semiconductor die disposed over the package substrate;
an interposer disposed over the semiconductor die and having a first bottom surface, a second bottom surface, and a sidewall connecting the first bottom surface and the second bottom surface;
an adhesive layer connecting the semiconductor die and the first bottom surface of the interposer; and
a conductive structure connecting the package substrate and the second bottom surface of the interposer.

11. The semiconductor package structure as claimed in claim 10, wherein a distance between the first bottom surface and the package substrate is greater than a distance between the second bottom surface and the package substrate.

12. The semiconductor package structure as claimed in claim 10, wherein the package substrate has a first top surface directly below the semiconductor die and a second top surface in contact with the conductive structure, wherein the first top surface and the second top surface form a stepped shape.

13. The semiconductor package structure as claimed in claim 10, wherein the distance between the first bottom surface and the package substrate is less than the distance between the second bottom surface and the package substrate.

14. The semiconductor package structure as claimed in claim 13, further comprising a molding material surrounding the first bottom surface, the semiconductor die, and the adhesive layer.

15. The semiconductor package structure as claimed in claim 10, wherein the first bottom surface has a larger projection area than the adhesive layer and/or the semiconductor die.

16. A semiconductor package structure, comprising:
a package substrate;
an interposer disposed over the package substrate and having a cavity;
a semiconductor die disposed over the package substrate and in the cavity; and
a molding material surrounding the semiconductor die and extending into the cavity.

17. The semiconductor package structure as claimed in claim 16, further comprising a conductive structure adjacent to the cavity and connecting the package substrate and the interposer.

18. The semiconductor package structure as claimed in claim 16, wherein a sidewall of the interposer, a sidewall of the molding material, and a sidewall of the package substrate are substantially coplanar.

19. The semiconductor package structure as claimed in claim 16, wherein a top surface of the interposer and a top surface of the molding material are substantially coplanar.

20. The semiconductor package structure as claimed in claim 19, wherein the top surface of the interposer and a top surface of the semiconductor die are substantially coplanar.
